(19) United States
(12) Patent Application Publication
(10) Pub. No.: US 2018/0180649 A1
(43) Pub. Date: Jun. 28, 2018

(54) INTEGRATED CURRENT SENSOR DEVICE AND CORRESPONDING ELECTRONIC DEVICE

(71) Applicant: STMicroelectronics S.r.l., Agrate Brianza (IT)

(72) Inventors: Dario Paci, Sedriano (IT); Paolo Angelini, Bologna (IT); Marco Del Sarto, Monza (IT)

(73) Assignee: STMicroelectronics S.r.l., Agrate Brianza (IT)

(21) Appl. No.: 15/586,903

(22) Filed: May 4, 2017

(30) Foreign Application Priority Data
Dec. 28, 2016 (IT) 102016000131871

(51) Int. Cl. G01R 15/20; G01R 19/00

(52) U.S. Cl. CPC G01R 15/202; G01R 19/0092

(57) ABSTRACT

An integrated current sensor device includes a supporting structure of conductive material, arranged within a package, and an integrated circuit die including a first and second magnetic-field sensor elements that are arranged along a sensor axis. An electronic circuit operatively coupled to the first and second magnetic-field sensor elements performs a differential detection of electric current. The supporting structure defines a current path for the electric current. The current path includes: a first path portion extending at the first magnetic-field sensor element; a second path portion extending at the second magnetic-field sensor element; and a third path portion that connects the first and second path portions. The first path portion and the second path portion are arranged on opposite sides of the sensor axis, and the third path portion crosses the sensor axis along a transverse axis.

### PRIORITY CLAIM

This application claims the priority benefit of Italian Application for Patent No. 102016000131871, filed on Dec. 28, 2016, the disclosure of which is hereby incorporated by reference in its entirety.

### TECHNICAL FIELD

Embodiments relate to an integrated current sensor device and to a corresponding electronic device.

### BACKGROUND

There are several applications in which current sensor devices for detecting the value of an electric current are required; for example, several industrial applications require the use of current sensor devices able to detect currents of a high value, even of the order of hundreds of Amperes.

In particular, known solutions envisage the use of Hall-effect current sensors, which are able to detect the magnetic field generated by the electric current flowing through a conductive line. As a function of the magnetic field detected, it is thus possible to determine the value of the electric current.

The use of Hall-effect sensors, or of similar magnetic-field sensors, for example of a magnetoresistive type, is advantageous in so far as these sensors generally have a low offset and a high stability of the same offset with respect to temperature; moreover, these sensors generally have low insertion losses.

For example, U.S. Pat. No. 5,041,780 (incorporated by reference) discloses a current sensor device using Hall-effect sensors for detecting the value of an electric current flowing through a conductor.

As shown in FIGS. 1A and 1B, this sensor device, designated by 1, comprises an electric current conductor 2, of a plane or “bus” type, having a longitudinal extension along a first horizontal axis x of a horizontal plane xy, and a conformation that narrows at a sensing portion 3. The conductor 2 has a pair of recesses 4a, 4b that define a portion of reduced section thereof, which constitutes the aforesaid sensing portion 3. The conductor 2 is, for example, coupled to a printed-circuit board (PCB), not illustrated herein.

A supporting substrate 5 is arranged on the conductor 2, at the sensing portion 3. Moreover, an integrated device (chip) 6 is arranged on the supporting substrate 5, in a position vertically corresponding to the sensing portion 3 of the conductor 2, being separated from the same conductor 2 by an insulation or shielding layer 7, of an electrically insulating material.

In particular, and as shown schematically, the integrated device 6 integrates a first magnetic-field sensor 8a and a second magnetic-field sensor 8b, which are of the Hall-effect type, so that the same sensors are arranged on opposite sides of the sensing portion 3 of the conductor 2, each at an end portion of a respective recess 4a, 4b. The aforesaid magnetic-field sensors 8a, 8b are aligned along a second horizontal axis y, which forms with the first horizontal axis x the aforesaid horizontal plane xy.

The integrated device 6 also integrates an electronic circuit (not illustrated herein), of a differential type, designed to process in a differential manner the detection signals generated by the magnetic-field sensors 8a, 8b, for generating an output detection signal.

This solution has a high sensitivity to the current to be detected and in general a good rejection of undesired effects due to further currents circulating in the same printed-circuit board. Differential detection further enables general reduction of the effects of interfering external fields.

In particular, as shown schematically in FIG. 2, an electric current I that flows along the conductor 2 determines a magnetic field B with opposite direction, at the first and second magnetic-field sensors 8a, 8b. Differential detection thus enables increase in the detection sensitivity.

Instead, a disturbance electric current I_{d}, which circulates along a different conductor 2′ of the same printed-circuit board, generates at the first and second magnetic-field sensors 8a, 8b magnetic fields B_{d}, B_{d}′ having the same direction. Differential detection thus enables reduction of the effect of these disturbance currents.

In greater detail, it may be shown that the magnetic field at the magnetic-field sensors 8a, 8b is a function of the ratio between the current that generates the magnetic field and the distance between the line in which the current flows and the position of the magnetic sensor.

On the hypothesis of the distance between the magnetic-field sensors 8a, 8b being negligible with respect to the distance from the line in which current flows, and of the value of the disturbance current being lower than the sensing current, the solution described in general enables a good disturbance reduction.

The Inventors have, however, realized and verified that there are applications and operating conditions in which, notwithstanding the above differential-detection scheme, the solution described previously does not enable elimination, or reduction below a desired level, of the effect of the disturbance currents (or of disturbance magnetic fields).

In particular, detection errors due to disturbances are in any case important, in the case where disturbance currents flow in the PCB having a high value, at least in given operating conditions higher than that of the current to be detected.

This is the case, for example, of PCBs of power devices, such as three-phase inverters, which generally comprise three electrical lines in parallel in which current flows, one for each electric phase. Detection of the current that flows along an electrical line may be jeopardized by the presence of a high current that flows along one of the other electrical lines, especially in the case where the current to be detected has a low value.

There is a need in the art to solve, at least in part, the problems highlighted previously in order to provide an improved solution for an integrated current sensor device.

### SUMMARY

An integrated current sensor device and a corresponding electronic device are provided to address the noted problems.

In an embodiment, an integrated current sensor device comprises: a package; a supporting structure of conductive material, arranged within the package; and an integrated circuit die, carried by said supporting structure within said package and integrating a first magnetic-field sensor element and a second magnetic-field sensor element arranged aligned along a sensor axis, and an electronic circuit operatively coupled to said first magnetic-field sensor element and second magnetic-field sensor element for implementing a differential detection. The supporting structure defines a current path for an electric current to flow within said package, said current path having: a first current path portion extending at said first magnetic-field sensor element on a first side of the sensor axis; a second current path portion extending at said second magnetic-field sensor element on a second side of the sensor axis opposite the first side; and a third current path portion connecting said first current path portion to said second current path portion and crossing said sensor axis between the first and second magnetic-field sensor elements.

In an embodiment, an integrated current sensor device comprises: an electrically conducting bridge having a first groove and a second groove, wherein the first and second grooves each extend along a transverse axis perpendicular to a sensor axis, with the first and second grooves positioned on opposite sides of said sensor axis, and each of the first and second grooves having an end portion located at said sensor axis; a first integrated magnetic-field sensor element positioned at said sensor axis and located at the end portion of the first groove; a second integrated magnetic-field sensor element positioned at said sensor axis and located at the end portion of the second groove; wherein said first and second grooves define a current path for an electric current to flow through the electrically conducting bridge, said current path having: a first current path portion passing adjacent to said first integrated magnetic-field sensor element on a first side of the sensor axis; a second current path portion passing adjacent to said integrated second magnetic-field sensor element on a second side of the sensor axis opposite the first side; and a third current path portion connecting said first current path portion to said second current path portion and crossing said sensor axis between the first and second integrated magnetic-field sensor elements.

### BRIEF DESCRIPTION OF THE DRAWINGS

For a better understanding of the present invention, preferred embodiments thereof are now described, purely by way of non-limiting example, with reference to the attached drawings, wherein:

FIG. 1A shows a top plan view of a current sensor device of a known type;

FIG. 1B shows a cross-sectional view of the current sensor device of FIG. 1A;

FIG. 2 is a schematic representation relating to current detection by the current sensor device of FIG. 1A;

FIG. 3A is a bottom perspective view of an integrated current sensor device according to one embodiment of the present solution;

FIG. 3B is a top perspective view of the integrated current sensor device of FIG. 3A;

FIG. 4A is a bottom view of a portion of the integrated current sensor device of FIG. 3A;

FIG. 4B is a top plan view of the portion of the integrated current sensor device of FIG. 4A;

FIG. 5 is a schematic view of a portion of the integrated current sensor device of FIG. 3A;

FIG. 6 is a schematic perspective view of a portion of an electronic device in which the integrated current sensor device of FIG. 3A is used; and

FIGS. 7 and 8 are schematic top plan views of a portion of the integrated current sensor device, according to variant embodiments of the present solution.

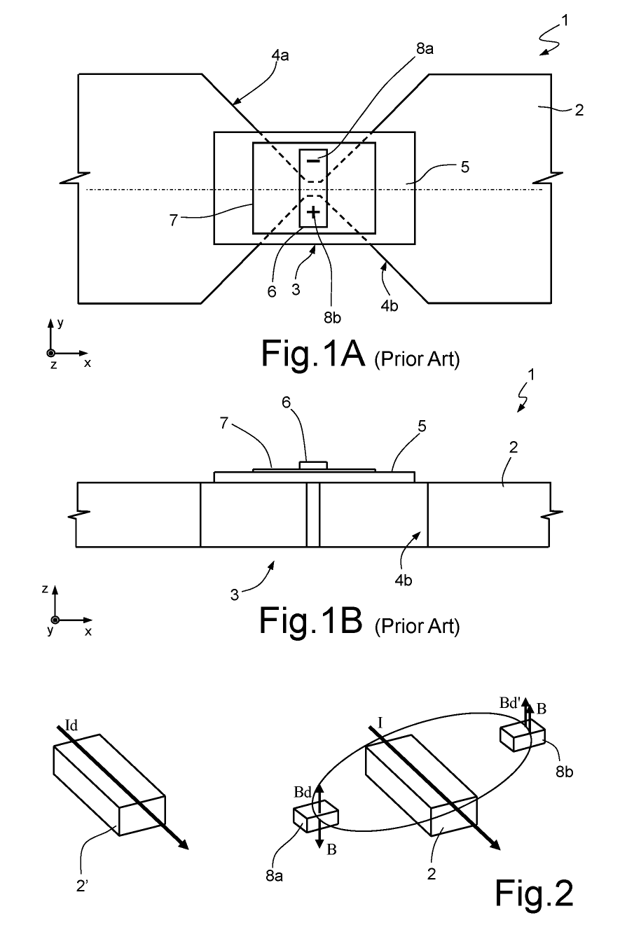

### DETAILED DESCRIPTION

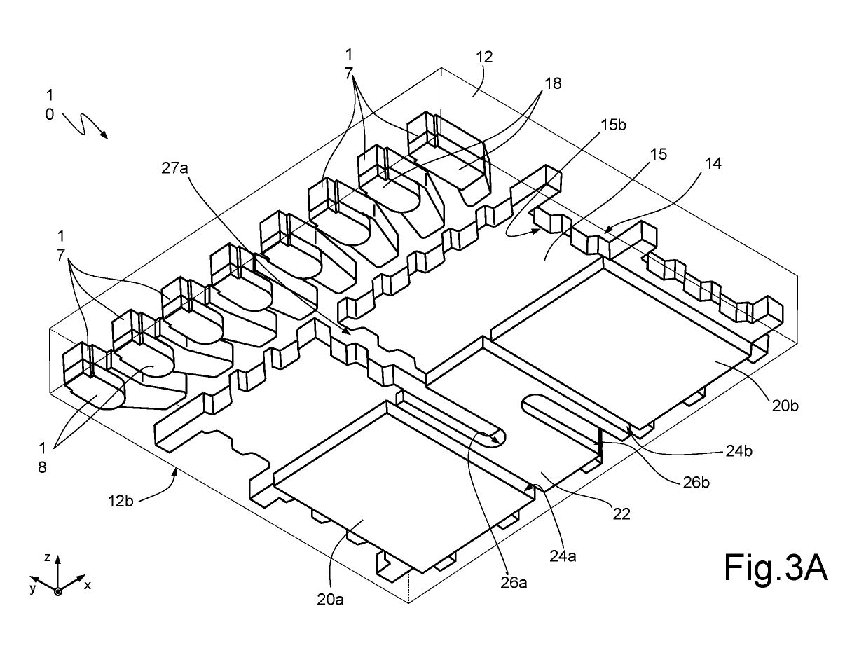

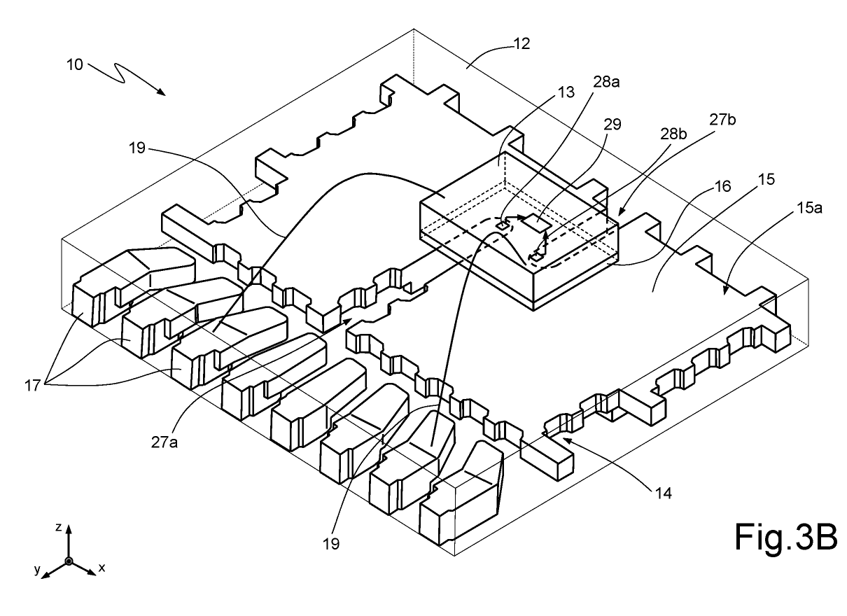

With initial reference to FIGS. 3A and 3B, an integrated current sensor device 10, according to one embodiment of the present solution, comprises: a package 12, including a coating of plastic material, for example epoxy resin; a die 13 of semiconductor material, in particular silicon, integrating electronic circuits and components (as described better hereinafter); and a supporting structure arranged within the package 12 and designed to carry the die 13 inside the package 12 and to provide the electrical connection towards the outside for the electronic circuit and components integrated within the same die 13.

As described hereinafter, the supporting structure, of conductive material, is further configured to define an appropriate current path within the package 12, for a current to be detected coming from an electrical line to which the integrated current sensor device 10 is coupled.

In particular, the aforesaid supporting structure comprises a leadframe 14, which in turn comprises: a die pad 15, made, for example, of copper and having a thickness of 500 μm, which has a main extension in a horizontal plane xy, is arranged entirely within the package 12, and has a top surface 15a (that lies in the horizontal plane xy) coupled to which is the die 13, via interposition of an insulating layer 16, made, for example, of glass and having a thickness of 50 μm; and a plurality of leads 17, which are distinct and separate from the die pad 15 and have an end portion flush with a side wall of the package 12 (which is arranged along a vertical axis z, transverse to the aforesaid horizontal plane xy).

In particular, the end portion of each lead 17 is coupled to a contact pad 18, of metal material, for example tin, which protrudes out of the package 12, or is flush with a bottom surface 12b of the same package 12, designed for mechanical and electrical coupling to a PCB (not illustrated herein) of an electronic device in which the integrated current sensor device 10 is used.

The die 13 is electrically connected to the leads 17 by electrical bond wires 19, which extend starting from a respective contact pad (not illustrated), carried by a top surface of the die 13 not in contact with the die pad 15, and a respective lead 17. The electrical bond wires 19 carry electrical signals from the electronic circuit and components integrated in the die 13 towards the outside of the package 12 and possibly control and driving signals from outside the package 12 to the aforesaid electronic circuit and components.

According to a particular aspect of the present solution, a first current pad 20a and a second current pad 20b, are coupled underneath a bottom surface 15b of the die pad 15, in contact therewith; the first and second current pads 20a, 20b are made of metal material, for example tin, having in the example a rectangular or square conformation in the horizontal plane xy and, for example, a thickness of approximately 250 μm. These current pads 20a, 20b protrude out of the package 12 or are arranged flush with the bottom surface 12b of the same package 12, and are designed for coupling (as shown hereinafter) with a first portion and a second portion of an electrical-conduction line (not illustrated herein), along which a current to be detected flows.

The first and second current pads 20a, 20b are arranged aligned along a first horizontal axis x of the horizontal plane xy, at opposite end portions of the die pad 15 along the same first horizontal axis x.

Moreover, a bridge element 22 is arranged between the current pads 20a, 20b, once again underneath the die pad 15 and in contact therewith; the bridge element 22 is also made of material metal, for example tin, and has the same thickness as the current pads 20a, 20b. Also this bridge element 22 protrudes out of the package 12, or is arranged flush with the bottom surface 12b of the same package 12.

In particular, the bridge element 22 is separated from the current pads 20a, 20b, along the first horizontal axis x, by a first slit 24a and a second slit 24b, which extend along a second horizontal axis y of the horizontal plane xy (transverse to the aforesaid first horizontal axis x), throughout the corresponding extension of the bridge element 22.

Moreover, the bridge element 22 has internally a first groove 26a and a second groove 26b, which also extend along the second horizontal axis y, this time for approximately half the corresponding dimension of the bridge element 22. In particular, each groove 26a, 26b extends through a respective half in which the bridge element 22 is divided by a sensor axis A, in this embodiment parallel to the first horizontal axis x and coinciding with a median axis of the bridge element 22.

In other words, the first groove 26a extends from an external wall of the bridge element 22 up to the aforesaid sensor axis A, and the second groove 26b extends from the sensor axis A itself up to the opposite external wall of the bridge element 22. The first and second grooves 26a, 26b are, in the example but not necessarily, symmetrical with respect to the centre of the bridge element 22, in the horizontal plane xy.

It should be noted that, within the package 12 of the integrated current sensor device 10, the aforesaid grooves 26a, 26b, as likewise the slits 24a, 24b are totally filled with the epoxy resin of the coating of the same package 12.

The die pad 15 has a respective first groove 27a and a respective second groove 27b, which are arranged vertically corresponding to, and communicating with, the aforesaid grooves 26a, 26b of the bridge element 22, and which are also totally filled with the epoxy resin of the package 12.

According to a further aspect of the present solution, the die 13 is arranged on the die pad 15 so as to be superimposed vertically both on the first groove 26a and on the second groove 26b, in particular above an end portion thereof at the sensor axis A.

Furthermore, the die 13 integrates a first magnetic-field sensor 28a and a second magnetic-field sensor 28b, in particular of the Hall-effect type (shown schematically in FIG. 3B), which are arranged aligned along the aforesaid sensor axis A (and in a region corresponding to the sensor axis A), above a respective one between the first and second grooves 26a, 26b. In the embodiment illustrated in the aforesaid FIG. 3B, the first and second magnetic-field sensors 28a, 28b are arranged at the center of the respective groove 26a, 26b (with respect to the first horizontal axis x).

The die 13 further integrates an electronic circuit 29 (so-called ASIC—Application Specific Integrated Circuit), operatively coupled to the first and second magnetic-field sensors 28a, 28b, in particular designed to implement an operation of differential amplification of corresponding magnetic-field-detection signals, to output an electrical signal indicative of the value of the detected current, as a function of the difference between the detection signals.

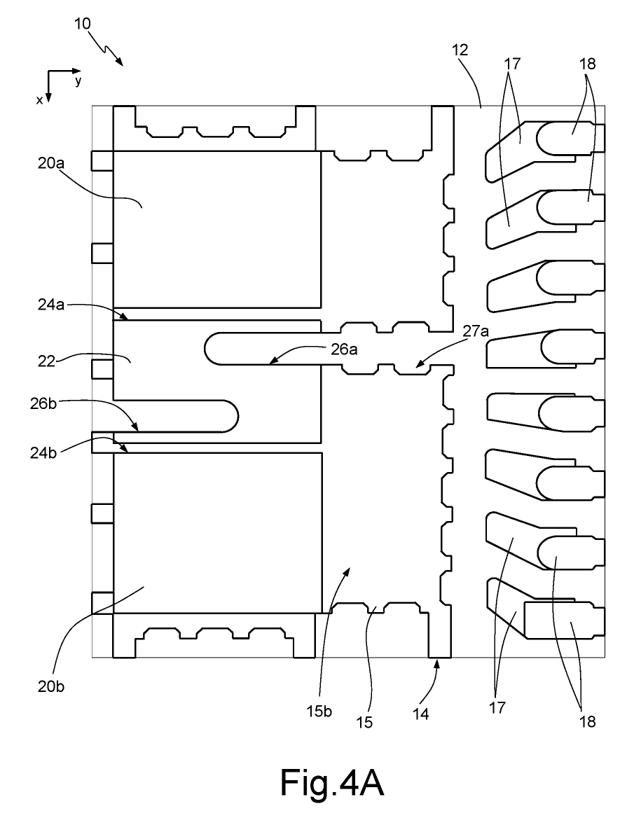

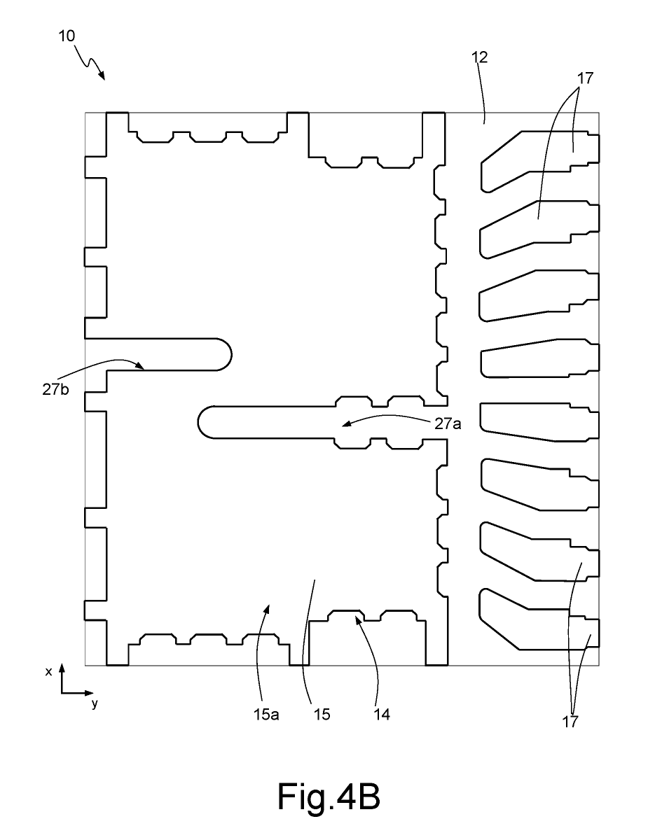

FIG. 4A shows a view from beneath of just the leadframe 14, with the coupled first and second current pads 20a, 20b and the coupled bridge element 22, whereas FIG. 4B shows a top plan view of the same leadframe 14 (the die 13 is not illustrated herein for clarity reasons).

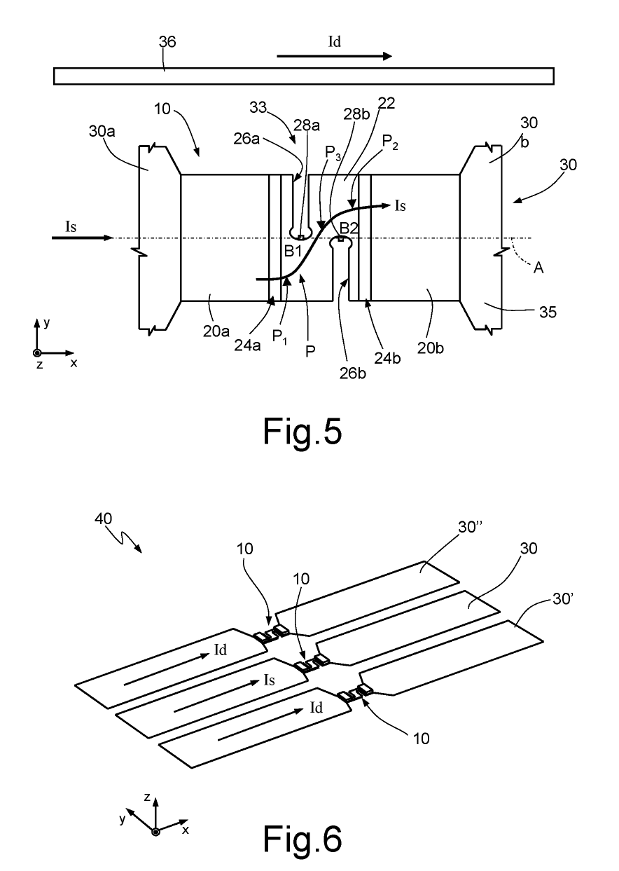

In use, and with reference also to the schematic representation of FIG. 5, the integrated current sensor device 10 is coupled to an electrical conduction line 30, through which a sensing current Is, the value of which is to be detected, flows.

In particular, the electrical conduction line 30 is coupled to a printed-circuit board 35 of an electronic device (not illustrated herein), has a longitudinal extension along the first horizontal axis x and is constituted by two line portions 30a, 30b, distinct from one another, which narrow at a sensing area 33.

The integrated current sensor device 10 is coupled to the electrical conduction line 30 at this sensing area 33. In particular, the first current pad 20a is electrically and mechanically coupled to the first line portion 30a, and the second current pad 20b is electrically and mechanically coupled to the second line portion 30b.

The sensing current Is consequently enters the package 12 through the first current pad 20a and comes out of the package 12 from the second current pad 20b. The bridge element 22 constitutes an electrical-conduction bridge between the first and second current pads 20a, 20b within the package 12, enabling passage of the sensing current Is from the first current pad 20a to the second current pad 20b.

In particular, the bridge element 22 has an S shape in plan view and thus defines a substantially S-shaped current path P for the sensing current Is, constituted by: a first portion P1, which has a main extension substantially along the first horizontal axis x and is arranged on a first side of the sensor axis A with respect to the second horizontal axis y (transverse to the aforesaid sensor axis A); a second portion P2, which has a main extension substantially along the first horizontal axis x and is arranged on a second side of the sensor axis A with respect to the second horizontal axis y, opposite to the first portion P1; and a third portion P3, which connects the first and second portions P1, P2 and has an extension transverse to the first horizontal axis x, crossing the sensor axis A.

As shown once again in FIG. 5, this current path P generates, at the first and second magnetic-field sensors 28a, 28b, magnetic fields B1, B2 having substantially the same value, given that they originate from the same value of sensing current Is and given that the magnetic-field sensors 28a, 28b are arranged substantially at a same distance from the respective first or second portions P1, P2 of the current path P and from the third portion P3 of the same current path P. Moreover, the aforesaid magnetic fields B1, B2 have an opposite sign (or direction):

B1(Is)=−B2(Is)=Bs

where Bs is the common magnetic field value due to the sensing current Is.

The differential-detection scheme implemented by the electronic circuit 29 processes the difference between the detection signals indicative of the magnetic fields B1 and B2, in this way guaranteeing a high sensitivity of detection:

B1(Is)−B2(Is)=2Bs

Instead, a disturbance current Id that flows along a different electrical line 36 on the same PCB 35, in the example having an extension parallel to the electrical-conduction line 30, generates magnetic fields having the same value and the same direction at the magnetic-field sensors 28a, 28b:

B1(Id)=B2(Id)=Bd

where Bd is the common magnetic field value due to the disturbance current Id.

The differential-detection scheme again performs processing of the difference between the magnetic fields B1 and B2, which in this case is substantially zero:

B1(Id)−B2(Id)=0

The current sensor device 10 thus has a high sensitivity to the sensing current Is and a high insensitivity with respect to the disturbance current Id.

In other words, the configuration of the current path P and the arrangement of the magnetic-field sensor elements 28a, 28b give rise to a gradient of magnetic field in a direction parallel to the sensor axis A (or to the first horizontal axis x, or to the direction of extension of the electrical-conduction line 30) due to the sensing current Is, whereas the magnetic field due to disturbance currents Id that circulate along different electrical lines 36, parallel to the aforesaid electrical-conduction line 30, is substantially constant.

The advantages of the solution proposed emerge clearly from the foregoing description.

In any case, it is again emphasized that the integrated current sensor device 10 has a high sensitivity to the current to be detected and a high insensitivity to the disturbance currents or magnetic fields.

It should be noted in particular that the effects of the magnetic fields due to the disturbance currents Id cancel out, whatever the value of the disturbance currents Id (in particular, also in the case where this value is high).

Further advantageous is the fact that the bridge element 22 is arranged partially on the outside of the coating of the package 12, or flush with the coating itself, thus constituting a heat-dissipation element.

The above characteristics are particularly advantageous in the case of use in power electronic devices, such as three-phase inverter devices.

In this regard, FIG. 6 shows a portion of an inverter device 40, which comprises three electrical-conduction lines 30, 30′, 30″, parallel to one another (in the example along the first axis x), each designed to carry the electric current of a respective phase.

The inverter device 40 comprises three integrated current sensor devices 10, one for each electrical-conduction line 30, 30′, 30″, each made and configured as described previously in detail. The electrical-conduction lines 30, 30′, 30″ and the integrated current sensor devices 10 are coupled to a same PCB 35.

Advantageously, also in the case where, as in the example shown, the sensing current Is that flows along one of the electrical-conduction lines 30, for example with a value of 2 A, is much lower than the disturbance currents Id that flow along the other electrical-conduction lines 30′, 30″, for example with a value of 200 A, the respective integrated current sensor device 10 is able to detect with a high sensitivity this sensing current Is, presenting a high insensitivity to the disturbance currents Id.

Finally, it is clear that modifications and variations may be made to what has been described and illustrated herein, without thereby departing from the scope of the present invention, as defined in the annexed claims.

In particular, the arrangement of the grooves 26a, 26b may vary with respect to what has been described previously.

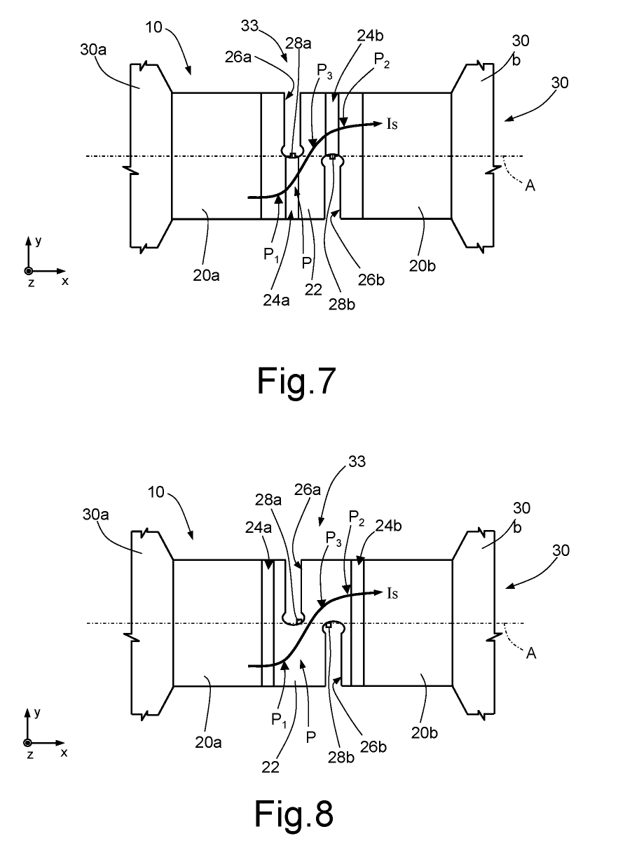

For example, as shown schematically in FIG. 7, the grooves 26a, 26b may be aligned along the second horizontal axis y to the slits 24a, 24b, being arranged at the same slits 24a, 24b and in fluidic communication therewith.

The length of the first groove 26a could further differ from that of the second groove 26b, in this case the grooves not being symmetrical with respect to the center of the bridge element 22.

Furthermore, the position of the magnetic-field sensors 28a, 28b could be different.

For example, as shown schematically in FIG. 8, the magnetic-field sensors 28a, 28b could be arranged in a staggered position with respect to the center of the respective groove 26a, 26b, in a position where they are closer together along the sensor axis A. This solution may allow to achieve an even greater insensitivity to disturbance, at the expense of a possible lower sensitivity of detection, in the case where other sources of disturbance are present that generate a gradient of magnetic field along the first horizontal axis x.

Moreover, the same magnetic-field sensors 28a, 28b could be of a type different from the Hall-effect sensors described previously, for example of a magnetoresistive type, or of a further appropriate type capable of detecting a vertical magnetic field component.

1. An integrated current sensor device, comprising:
a package;
a supporting structure of conductive material, arranged within the package; and
an integrated circuit die, carried by said supporting structure within said package and integrating a first magnetic-field sensor element and a second magnetic-field sensor element arranged aligned along a sensor axis, and an electronic circuit operatively coupled to said first magnetic-field sensor element and second magnetic-field sensor element for implementing a differential detection,
wherein said supporting structure defines a current path for an electric current to flow within said package, said current path having: a first current path portion extending at said first magnetic-field sensor element on a first side of the sensor axis; a second current path portion extending at said second magnetic-field sensor element on a second side of the sensor axis opposite the first side; and a third current path portion connecting said first current path portion to said second current path portion and crossing said sensor axis between the first and second magnetic-field sensor elements.

2. The sensor device according to claim 1, wherein said supporting structure comprises:
a supporting element having a top surface to which said die is attached via interposition of an insulation layer, and a bottom surface;
a first contact pad and a second contact pad coupled to, and in contact with, said bottom surface; and
a bridge element, of a conductive material, which is arranged between said first and second contact pads and has a shape that defines said current path.

3. The sensor device according to claim 2, wherein said bridge element has a first groove and a second groove, extending along a transverse axis perpendicular to said sensor axis, the first and second grooves positioned on opposite sides of said sensor axis, each of the first and second grooves having an end portion at said sensor axis, said first and second grooves defining said current path; wherein said first magnetic-field sensor element is located at the end portion of the first groove and said second magnetic-field sensor element is located at the end portion of said second groove.

4. The sensor device according to claim 3, wherein said bridge element has a median axis, and wherein said sensor axis coincides with said median axis; and wherein said first and second magnetic-field sensor elements are arranged along said median axis.

5. The sensor device according to claim 3, wherein said supporting element has a first groove and a second groove, and wherein the first and second grooves of the supporting element are arranged to coincide with the first and second grooves of said bridge element.

6. The sensor device according to claim 3, wherein said first magnetic-field sensor element is arranged at a center of the end portion of the first groove and said second magnetic-field sensor element is arranged at a center of the end portion of the second groove.

7. The sensor device according to claim 3, wherein said first contact pad is separated from said bridge element by a first slit extending parallel to said transverse axis; and said second contact pad is separated from said bridge element by a second slit extending parallel to said transverse axis.

8. The sensor device according to claim 2, wherein said package comprises a coating, and wherein said first and second contact pads are accessible from the outside of said coating of said package.

9. The sensor device according to claim 8, wherein said bridge element is accessible from the outside of said coating of said package.

10. The sensor device according to claim 3, wherein said first magnetic-field sensor element and said second magnetic-field sensor element are magnetic sensors configured to detect a magnetic field directed along a vertical axis that is orthogonal to a horizontal plane defined by said sensor axis and by said transverse axis.

11. The sensor device according to claim 10, wherein said first magnetic-field sensor element and said second magnetic-field sensor element are Hall-effect sensors.

12. The sensor device according to claim 1, further comprising a plurality of leads electrically coupled to said die, which is carried by said supporting structure, by electrical wires contained within said package.

13. An electronic device, comprising:
a printed-circuit board to which a first conductive line is coupled, said first conductive line having a first line portion and a second line portion, distinct and separate from one another;
an integrated current sensor device coupled to said printed-circuit board between said first line portion and said second line portion, wherein the integrated current sensor device comprises:
a package;
a supporting structure of conductive material, arranged within the package; and
an integrated circuit die, carried by said supporting structure within said package and integrating a first magnetic-field sensor element and a second magnetic-field sensor element arranged aligned along a sensor axis, and an electronic circuit operatively coupled to said first magnetic-field sensor element and second magnetic-field sensor element for implementing a differential detection,
wherein said supporting structure defines a current path for an electric current to flow within said package, said current path having: a first current path portion extending at said first magnetic-field sensor element on a first side of the sensor axis; a second current path portion extending at said second magnetic-field sensor element on a second side of the sensor axis opposite the first side; and a third current path portion connecting said first current path portion to said second current path portion and crossing said sensor axis between the first and second magnetic-field sensor elements;
wherein said first current path portion is electrically coupled to said first line portion and said second current path portion is electrically coupled to said second line portion, and wherein said electric current flows from said first line portion to said second line portion through said current path defined in said integrated current sensor device.

14. The electronic device according to claim 13, wherein said supporting structure of said integrated current sensor device comprises:
a supporting element having a top surface, to which said die is coupled, and a bottom surface;
a first contact pad and a second contact pad coupled to, and in contact with, said bottom surface; and
a bridge element, of a conductive material, which is arranged between said first and second contact pads and has a shape that defines said current path;
wherein said first current pad is electrically coupled to said first line portion on said printed-circuit board, and said second current pad is electrically coupled to said second line portion on said printed-circuit board; and wherein said first conductive line extends along a horizontal axis parallel to said sensor axis.

15. The electronic device according to claim 13, further comprising:
a second conductive line coupled to said printed-circuit board and arranged alongside and parallel to said first conductive line; and
a further integrated current sensor device coupled to said printed-circuit board and electrically coupled to the second conductive line.

16. The electronic device according to claim 15, further comprising:
a third conductive line coupled to said printed-circuit board and arranged alongside and parallel to said first conductive line on an opposite side of said first conductive line from said second conductive line; and
another integrated current sensor device coupled to said printed-circuit board and electrically coupled to the third conductive line.

17. An integrated current sensor device, comprising:
an electrically conducting bridge having a first groove and a second groove, wherein the first and second grooves each extend along a transverse axis perpendicular to a sensor axis, with the first and second grooves positioned on opposite sides of said sensor axis, and each of the first and second grooves having an end portion located at said sensor axis;
a first integrated magnetic-field sensor element positioned at said sensor axis and located at the end portion of the first groove;
a second integrated magnetic-field sensor element positioned at said sensor axis and located at the end portion of the second groove;
wherein said first and second grooves define a current path for an electric current to flow through the electrically conducting bridge, said current path having:
a first current path portion passing adjacent to said first integrated magnetic-field sensor element on a first side of the sensor axis;
a second current path portion passing adjacent to said integrated second magnetic-field sensor element on a second side of the sensor axis opposite the first side; and
a third current path portion connecting said first current path portion to said second current path portion and crossing said sensor axis between the first and second integrated magnetic-field sensor elements.

18. The integrated current sensor device of claim 17, wherein said first and second grooves define the electrically conducting bridge to have an S shape in plan view.

19. The integrated current sensor device of claim 17, further comprising a first electrical contact pad electrically connected to a first end of the electrically conducting bridge at the first current path portion and a second electrical contact pad electrically connected to a second end of the electrically conducting bridge at the second current path portion.

20. The integrated current sensor device of claim 17, wherein said first magnetic-field sensor element is arranged at a center of the end portion of the first groove and said second magnetic-field sensor element is arranged at a center of the end portion of the second groove.

21. The integrated current sensor device according to claim 17, wherein said first integrated magnetic-field sensor element and said second integrated magnetic-field sensor element are magnetic sensors configured to detect a magnetic field directed along a vertical axis that is orthogonal to a horizontal plane defined by said sensor axis and by said transverse axis.

22. The integrated current sensor device according to claim 21, wherein said first integrated magnetic-field sensor element and said second integrated magnetic-field sensor element are each a Hall-effect sensor.
